(19) United States
(12) Patent Application Publication
(10) Pub. No.: US 2012/0262857 A1
(43) Pub. Date: Oct. 18, 2012

(54) TERMINAL APPARATUS AND HINGE STRUCTURE

(75) Inventors: Yuji FUKAYA, Tokyo (JP); Tatsuhito Aono, Tokyo (JP); Maki Ohuchi, Tokyo (JP)

(73) Assignee: Sony Mobile Communications Inc., Minato-ku (JP)

(21) Appl. No.: 13/445,318

(22) Filed: Apr. 12, 2012

Related U.S. Application Data
(60) Provisional application No. 61/474,832, filed on Apr. 13, 2011.

(51) Int. Cl. H05K 5/00

(52) U.S. Cl. 361/679.01

(57) ABSTRACT

A terminal apparatus that includes a first housing, a second housing, and a hinge mechanism that slidably couples the first housing to the second housing in each of an open state and a closed state with respect to the second housing. The hinge mechanism includes a base portion and a movable portion, the movable portion being slidable with respect to the base portion in a direction which the first housing moves away from the second housing when the first housing transitions from the closed state to the open state with respect to the second housing.

### CROSS REFERENCE TO RELATED APPLICATION

The present application claims the benefit of the earlier filing date of U.S. Provisional Patent Application Ser. No. 61/474,832 filed on Apr. 13, 2011, the entire contents of which is incorporated herein by reference.

### BACKGROUND OF THE DISCLOSURE

1. Field of the Disclosure

The present disclosure relates to a portable terminal including first and second housings coupled to each other through a hinge portion, and to a hinge structure for the portable terminal.

2. Description of Related Art

Hitherto, for various portable terminals such as cellular phone terminals, small-sized PCs, and game machines, there has been a strong demand to reduce the size (especially, the width) of a housing of a portable terminal in order to put the portable terminal in a pocket, hold the portable terminal with one hand, and so forth. On the other hand, it is desirable that a display screen and an operating section should be large for convenience of use. In order to achieve both the size reduction for portability and the convenience of use, so-called clamshell-type portable terminals (mobile terminals) are widely utilized.

A clamshell-type portable terminal basically includes first and second housings coupled to each other through a hinge portion.

FIG. 1 shows an exemplary clamshell-type portable terminal according to the related art. The portable terminal includes a first housing in which a display is disposed and a second housing in which a keyboard is disposed, which are coupled to each other through a hinge portion. The portable terminal is a so-called horizontally opening portable terminal in which the hinge portion is provided along the long side of the first and second housings. In the example shown, a rotary shaft of the hinge portion is provided on the second housing side. In this configuration, the hinge portion extends to a location below a display screen, and thus the vertical size (length of the short side) Y1 of the display screen of a display device housed in the first housing is considerably restricted compared to the actual size of the first housing because of the presence of the hinge portion with a size Y2.

In the portable terminal shown in FIG. 1, the width (X1) of a hinge area may be restricted so that the hinge portion does not extend to a location below the display screen as shown in FIG. 2. This makes it possible to increase the screen size by lowering the lower end of the display screen as much as possible. In the configuration of FIG. 2, however, in a state (open state) in which the first housing is open with respect to the second housing, the lower end portion of the display screen may be hidden behind the rear end portion of the second housing and may be difficult to see.

In order to address such an issue, a configuration in which a notch is formed at the rear end portion of the second housing along the longitudinal direction of the second housing as shown in FIG. 3(a) to make the lower end portion of the display screen easily visible is known. In this configuration, however, when the portable terminal is seen from the second housing side in a state (closed state) in which the first housing is closed with respect to the second housing, a notched portion C may be conspicuous and the display screen may be partially exposed through the notched portion C as shown in FIG. 3(b).

In order to address such an issue, the rotary shaft of the hinge portion may be provided on the side of the first housing which houses the display device as shown in FIG. 4. In this configuration, the width (X1) of the hinge area may be restricted so that the hinge portion does not extend to a location below the display screen as shown in FIG. 4. This makes it possible to increase the screen size by lowering the lower end of the display screen as much as possible. Moreover, the lower end portion of the display screen is not hidden by the rear end portion of the second housing even in the open state. Thus, it is not necessary to provide a notched portion in the second housing. With the rotary shaft of the hinge portion provided on the first housing side, however, the thickness of the first housing is restricted by the diameter of the hinge portion. Therefore, it is necessary to make the first housing thicker than necessary even though currently the display device may be formed to be sufficiently thin. This results in an increase in thickness of the portable terminal in a folded state.

### SUMMARY OF THE DISCLOSURE

The present disclosure has been made in view of the foregoing background, and the inventors recognize the need to reduce the size and the thickness of a portable terminal including first and second housings coupled to each other through a hinge portion, by arranging components efficiently and without degrading the usability.

According to a first embodiment, the disclosure is directed to a terminal apparatus that includes a first housing, a second housing, and a hinge mechanism that slidably couples the first housing to the second housing in each of an open state and a closed state with respect to the second housing. The hinge mechanism includes a base portion and a movable portion, the movable portion being slidable with respect to the base portion in a direction which the first housing moves away from the second housing when the first housing transitions from the closed state to the open state with respect to the second housing.

According to an embodiment of the present disclosure, it is possible to reduce the size and the thickness of a portable terminal including first and second housings coupled to each other through a hinge portion, by arranging components efficiently and without degrading the usability, by using a hinge structure in which a part of a coupling member is movable along with an opening operation. In addition, it is possible to obtain a good viewability of a display screen in an open state without reducing the display area of a display device disposed in a first housing and without providing a notch in a part of the first housing.

### BRIEF DESCRIPTION OF THE DRAWINGS

FIG. 1 shows an exemplary clamshell-type portable terminal according to the related art.

FIG. 2 shows an exemplary clamshell-type portable terminal according to the related art in which the lower end of a display screen is lowered as much as possible to increase the screen size.

FIG. 3 illustrates another exemplary clamshell-type portable terminal according to the related art which addresses an issue of the clamshell-type portable terminal according to the related art of FIG. 2.

FIG. 4 illustrates still another exemplary clamshell-type portable terminal according to the related art.

FIGS. 5(a) to 5(c) illustrate a first embodiment of the present disclosure.

FIG. 6 shows a portable terminal shown in FIG. 5(a) in an open state to which the present disclosure is not applied.

FIGS. 7(a) to 7(c) show an exemplary configuration of a coupling member according to the first embodiment of the present disclosure.

FIG. 8 shows a portable terminal according to a second embodiment in which an upper housing performs a sliding operation in conjunction with an opening/closing operation of the upper housing.

FIGS. 9(a) and 9(b) show a coupling portion between the upper housing and a lower housing in the open state as seen from different angles, and FIG. 9(c) shows the coupling portion of FIG. 9(a) with some components removed.

FIGS. 10(a) to 10(c) show some constituent elements of the second embodiment in an exploded state.

FIG. 11 shows a helical spring housed inside a guide member according to the second embodiment.

FIG. 12 illustrates a specific operation of a coupling member in the portable terminal shown in FIG. 8, in which FIGS. 12(a) to 12(d) show the relationship between a cam portion and the coupling member (and a slide rod) at each stage, including intermediate stages, in the course in which the upper housing moves from a closed state to an open state at a predetermined angle.

FIGS. 13(a) and 13b illustrate a modification of the second embodiment.

FIGS. 14(a) to 14(d) illustrate a third embodiment of the present disclosure.

FIGS. 15(a) to 15(c) illustrate the configuration of a portion of the third embodiment of the present disclosure.

FIG. 16 shows some constituent elements of the third embodiment in an exploded state.

FIG. 17 shows a cross-sectional shape of a coupling member according to the third embodiment.

FIG. 18 illustrates the effect of the third embodiment.

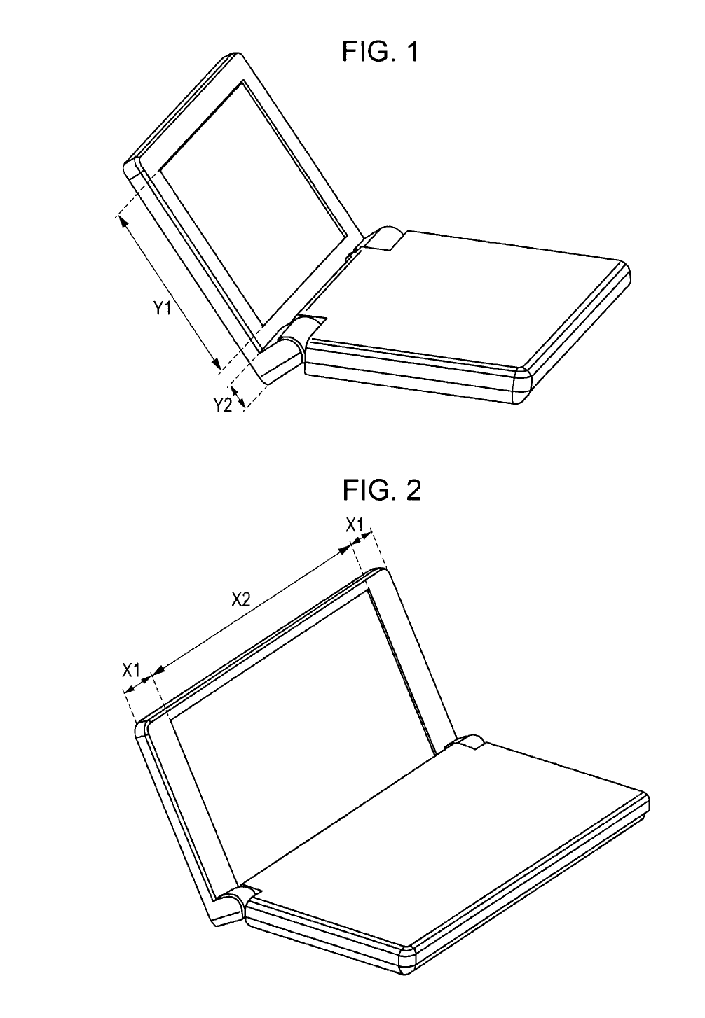

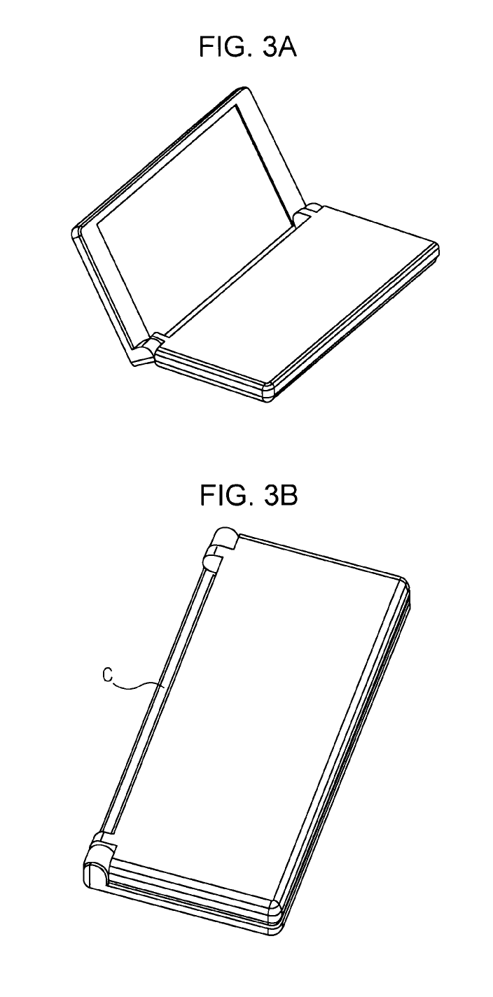

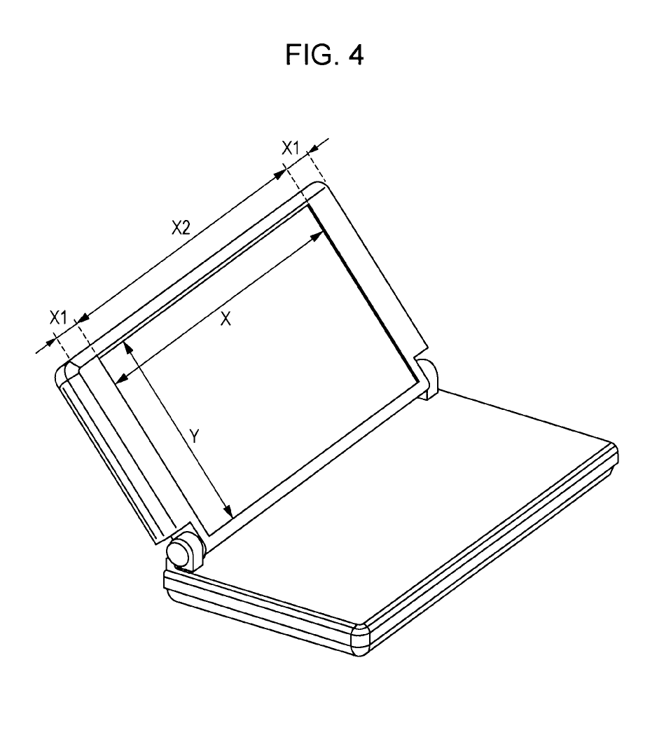

### DETAILED DESCRIPTION

Preferred embodiments of the present disclosure will be described in detail below.

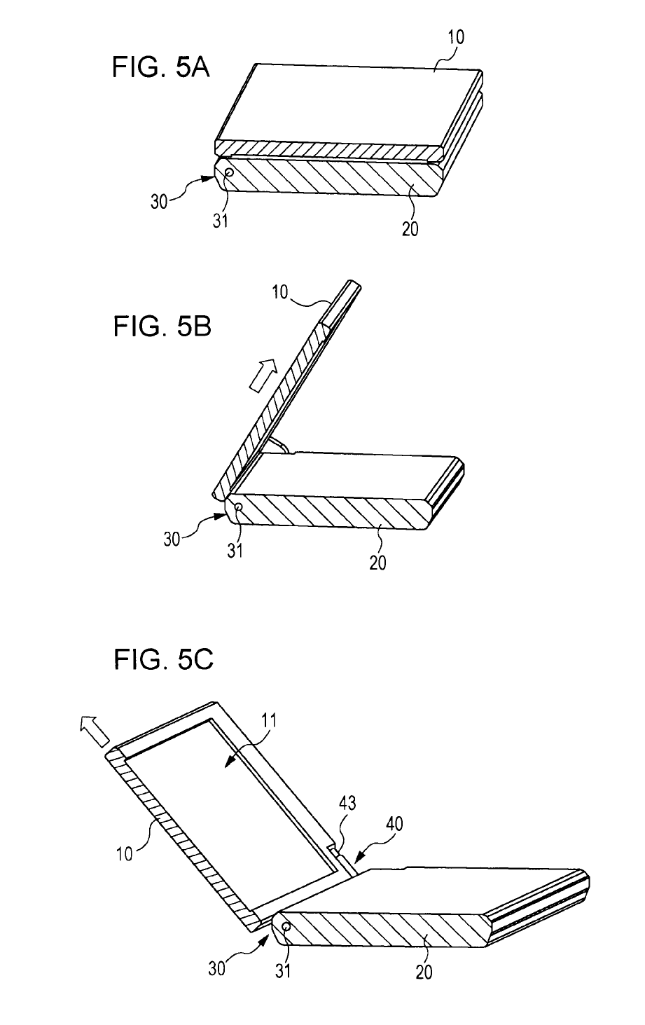

FIGS. 5(a) to 5(c) illustrate a first embodiment of the present disclosure. FIG. 5(a) shows a portable terminal in which an upper housing 10 serving as a first housing and a lower housing 20 serving as a lower housing 20 are coupled to each other through a hinge portion 30 in a closed state. For convenience, only a right side portion of the portable terminal obtained by cutting the portable terminal at a center portion is shown. The term “lower housing” as used herein refers to a housing that normally directly contacts a desk or a table when the portable terminal is placed on the desk or the table or that is normally supported or held by a hand of a user when the portable terminal is supported or held by the user.

The hinge portion 30 couples the upper housing 10 to the lower housing 20 so as to be rotatable about a rotary shaft. The rotary shaft (support shaft 31) of the hinge portion 30 is provided at the rear end portion of the lower housing 20.

A display device is disposed in the upper housing 10 with a display screen exposed. An operating section is disposed in the lower housing 20. The operating section may include a keyboard or a touch panel. Another display device may be disposed in the lower housing.

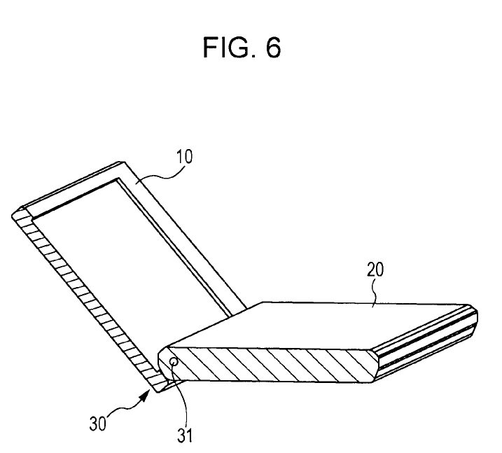

In a configuration according to the related art, when the upper housing 10 is opened with respect to the lower housing 20 from the closed state of FIG. 5(a), an open state shown in FIG. 6 is reached. In the open state, as described with reference to FIG. 2, the lower end portion of a display screen 11 is hidden behind the rear end portion of the lower housing 20 and may be difficult to see.

In contrast, the upper housing 10 is configured to be movable (slidable) together with the display screen 11 in the direction away from the hinge portion 30 (that is, away from the lower housing 20) in the course of transitioning from the closed state of FIG. 5(a) to an open state of FIG. 5(c) through an intermediate state of FIG. 5(b). In the embodiment, in the open state, the upper housing 10 may be slid upward (that is, in the direction away from the hinge portion 30) through a manual operation performed by the user. However, as discussed later, variations in distance of the upper housing 10 from the hinge portion 30 (or the lower housing 20) may be achieved automatically in conjunction with an opening/closing operation of the upper housing 10 with respect to the lower housing 20.

In any case, the movement between both the housings in the embodiment is achieved by a coupling member 40 provided in the hinge portion 30. The coupling member 40 includes a base portion 41 rotatably connected to the lower housing 20 and a movable portion (discussed later), one end of which is jointed (fixed) to the upper housing 10 and which is slidable with respect to the base portion 41. The movable portion is configured to be slidable with respect to the base portion 41 in the direction in which the upper housing 10 moves away from the lower housing 20 when the upper housing 10 transitions from a state of being closed with respect to the lower housing 20 to a state of being open with respect to the lower housing 20. In the configuration shown in FIG. 5, the coupling member 40 is provided at both the left and right ends of the lower end side of the upper housing 10 (rear end side of the lower housing 20) although left side portions of the housings are not shown.

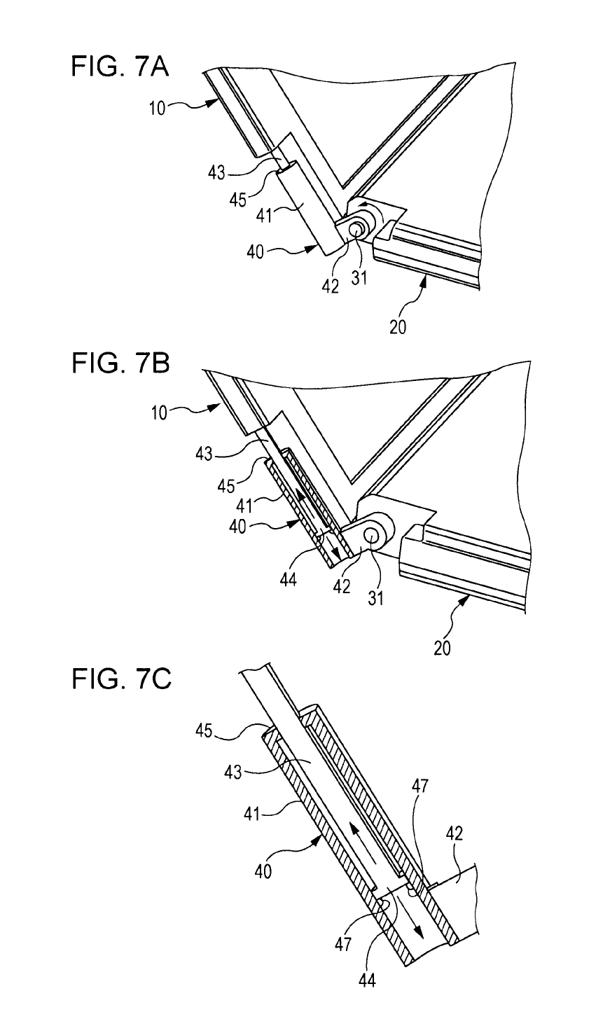

FIG. 7 shows an exemplary configuration of the coupling member 40 of the portable terminal shown in FIG. 5. In the example shown, the coupling member 40 provided at the left rear end portion of the lower housing 20 as seen from the front is shown in partially cutaway cross section. This configuration allows a manual sliding operation of the upper housing 10. Providing the coupling member 40 on both the left and right sides of the housing increases the stability of the opening/closing operation. However, the present disclosure does not exclude a configuration in which the coupling member 40 is provided on only one of the left and right sides of the housing.

More specifically, the coupling member 40 is formed by a slide rod (rod member) 43 serving as the movable portion and the base portion 41 which guides the slide rod 43 so as to be slidable along the longitudinal direction. The coupling member 40 includes the base portion 41 in the shape of a cylinder having a space inside which the slide rod 43 is slidable, and a shaft receiving portion 42 projecting in a lateral direction from one end of the base portion 41. The shaft receiving portion 42 is jointed to the support shaft 31 disposed at the rear end portion of the lower housing 20 to extend in parallel with the rear side of the lower housing 20, and rotatably supports the support shaft 31 serving as the rotary shaft. The support shaft 31 is fixed to the lower housing 20, and the shaft receiving portion 42 rotates about the support shaft 31. A mechanism that directly or indirectly applies to the upper housing 10 an urging force for maintaining the upper housing 10 in the open state in a predetermined opening angle range may be provided. Such a mechanism is not directly related to the present disclosure, and any existing mechanism may be utilized.

Instead of the configuration described above, the shaft receiving portion 42 may be fixed to the support shaft 31 so that the support shaft 31 rotates together with the shaft receiving portion 42 with respect to the lower housing 20. In this case, preferably, a mechanism that applies to the support shaft 31 an urging force for maintaining the upper housing 10 in the open state in a predetermined opening angle range may be provided.

One end (upper end) of the slide rod 43 passes through and extends out of an opening provided in an end wall surface 45 on the free end side of the coupling member 40 to be fixed to the upper housing 10. The other end (lower end) of the slide rod 43 has a large-diameter portion 44, the outer periphery of which slidably contacts the inner wall of the base portion 41. When the slide rod 43 slides upward inside the coupling member 40, the slide rod 43 is stopped with the large-diameter portion 44 contacting the end wall surface 45 of the coupling member 40. That is, the large-diameter portion 44 functions as a stopper that hinders the slide rod 43 from moving further upward.

In case of a manual operation, when the upper housing 10 is slid upward, the upper housing 10 is preferably held at at least the position after the movement through concave-convex engagement between the slide rod 43 and the base portion 41 which guides the sliding. The held state may be canceled by an operation force of the user.

As shown in FIG. 7(c), which shows the coupling member 40 as enlarged, for example, one or a plurality of retention portions 47 may be provided at predetermined positions on the inner wall surface of the base portion 41 of the coupling member 40. In the example shown, the retention portion 47 includes a projecting portion provided on the inner wall surface of the base portion 41. When the upper housing 10 transitions from the closed state to the open state, pulling the upper housing 10 outward pulls the slide rod 43 out of the coupling member 40. At this time, the large-diameter portion 44 moves from the lower end side toward the upper end side of the coupling member 40 to contact the retention portion 47. Thereafter, when a force for moving the slide rod 43 further upward is applied, the large-diameter portion 44 moves over the retention portion 47. The respective materials forming the guide member 41, the slide rod 43, and the support shaft 31 are not specifically limited as long as the guide member 41, the slide rod 43, and the support shaft 31 are each made of a rigid material. However, the coupling member 40 is preferably formed from such a material that allows the inside diameter of the coupling member 40 to be slightly elastically increased by a pressure from the inner side, depending on the configuration of the retention portion 47.

When the force for moving the slide rod 43 upward is canceled after the large-diameter portion 44 moves over the retention portion 47, the large-diameter portion 44 is retained by the retention portion 47 to be maintained at a retention position at which the upper housing 10 is pulled up. Pushing back the upper housing 10 downward moves the large-diameter portion 44 of the slide rod 43 over the retention portion 47 to return to the original, retracted position.

The retention portion 47 determines a position at which the upper housing 10 is held in a projecting state. Thus, the retention portion 47 may be provided at a plurality of locations on the path along the sliding direction of the slide rod 43. In this case, the upper housing 10 may be held in the projecting state with a plurality of selectable projecting amounts.

The retention portion 47 is not limited to a projecting portion. For example, the retention portion 47 may be formed by a ball embedded in the inner wall of the coupling member 40 and urged by a spring force toward the inner side of the coupling member 40, although not specifically shown. The retention portion 47 may also be formed by a plate spring curved in an arcuate shape toward the inner side of the coupling member 40. Alternatively, a plurality of magnets may be utilized to cause the slide rod 43 and the coupling member 40 to be attracted to each other at a predetermined position so that the upper housing 10 is held in the projecting state.

According to the first embodiment, it is possible to improve the viewability of the display screen by floating up the upper housing 10 from the lower housing 20 when the upper housing 10 is opened with respect to the lower housing 20.

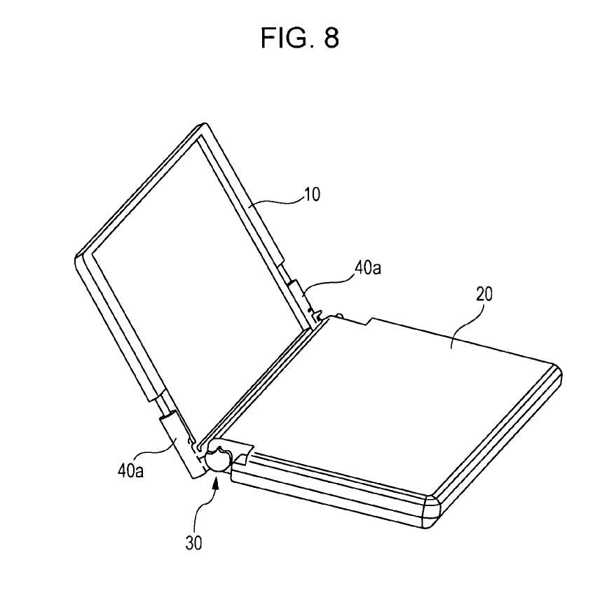

FIG. 8 shows a portable terminal according to a second embodiment in which the upper housing 10 performs a sliding operation in conjunction with an opening/closing operation of the upper housing 10. Elements that are the same as those shown in FIG. 7 are denoted by the same reference numerals.

In the embodiment, the upper housing 10 is maintained in the retracted state when the upper housing 10 is in the closed state, and the upper housing 10 is automatically projected upward when the user performs an opening operation without the need for the user to perform an operation to pull up the upper housing 10 as described above. Such an operation is achieved by a coupling member 40a. That is, when the upper housing 10 is rotated from a first rotational position at which the upper housing 10 is closed with respect to the lower housing 20 to a second rotational position at which the upper housing 10 is open with respect to the lower housing 20, the coupling member 40a functions as follows. That is, the slide rod 43 serving as the movable portion (and hence the upper housing 10) is moved in the direction away from the lower housing 20 in conjunction with the rotating operation. Conversely, the slide rod 43 (and hence the upper housing 10) is returned to the original position in the course in which the upper housing 10 is rotated from the second rotational position to the first rotational position.

A specific exemplary configuration and operation of the coupling member 40a will be described below.

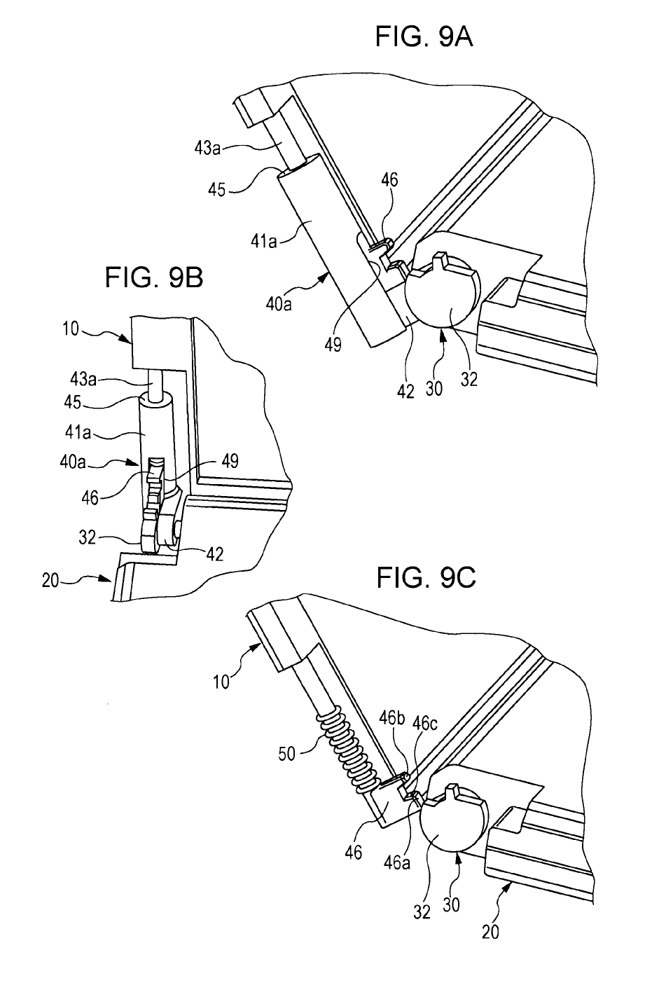

FIGS. 9(a) and 9(b) show a coupling portion between the upper housing 10 and the lower housing 20 in the open state as seen from different angles, and FIG. 9(c) shows the coupling portion of FIG. 9(a) with some components removed.

One end of a slide rod 43a according to the second embodiment is jointed (fixed) to the upper housing 10. The other end, which is a free end, of the slide rod 43a is provided with a key-shaped portion (concave-convex portion) 46. In the example shown, the key-shaped portion 46 includes two convex portions 46a and 46b and a concave portion 46c provided between the convex portions 46a and 46b. At the other end of the slide rod 43a, a base portion 41a supports the slide rod 43a so as to be slidable along the longitudinal direction of the slide rod 43a, and includes a groove portion 49 through which the key-shaped portion 46 passes during the sliding.

The hinge portion 30 includes a cam portion 32 exposed at a rear end side portion of the lower housing 20. The cam portion 32 is fixed to the lower housing 20, and engaged with the key-shaped portion 46 of the slide rod 43a when the shaft receiving portion 42 rotates. That is, the key-shaped portion 46 of the slide rod 43a engageably rotates with respect to the cam portion 32 of the hinge portion 30 in the course in which the upper housing 10 rotates from the first rotational position at which the upper housing 10 is closed with respect to the lower housing 20 to the second rotational position at which the upper housing 10 is open with respect to the lower housing 20. This allows the slide rod 43a to move upward and downward in the coupling member 40a.

A helical spring 50 is an elastic member housed inside the coupling member 40a with the slide rod 43 passing through a space inside the spiral shape. The function and the effect of the helical spring 50 will be discussed later.

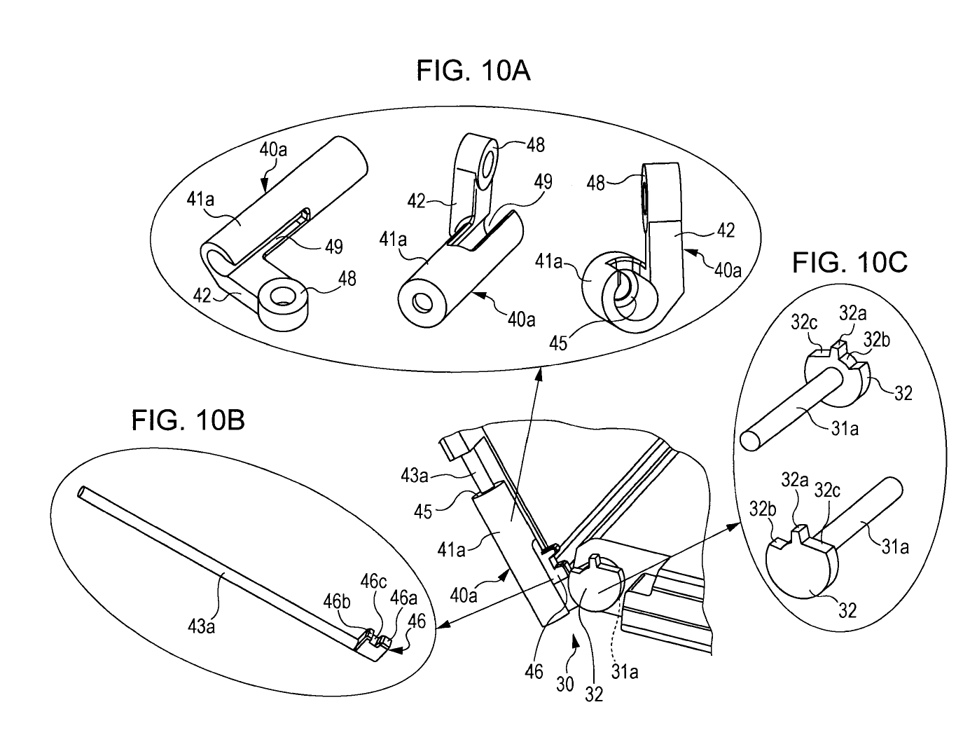

FIG. 10 shows some constituent elements shown in FIG. 9 in an exploded state.

The coupling member 40a is formed by the slide rod 43a and the base portion 41 which guides the slide rod 43a so as to be slidable along the longitudinal direction.

The base portion 41a has the shape of a cylinder having a space inside which the slide rod 43 is slidable. The shaft receiving portion 42 projects in a lateral direction from one end of the base portion 41a. The shaft receiving portion 42 is jointed to the support shaft 31a disposed at the rear end portion of the lower housing 20 to extend in parallel with the rear side of the lower housing 20, and rotatably supports the support shaft 31a serving as the rotary shaft. In the embodiment, the support shaft 31a is fixed to the lower housing 20, and the shaft receiving portion 42 rotates about the support shaft 31a. A mechanism that applies an urging force for maintaining the upper housing 10 in the open state in a predetermined opening angle range is provided separately from the support shaft 31a. For such a mechanism, any existing mechanism may be utilized.

The slide rod 43a has the key-shaped portion 46 at one end of the thin straight rod. In the example, the key-shaped portion 46 is configured such that the concave portion 46c is formed between the adjacent convex portions 46a and 46b.

As discussed earlier, the base portion 41a of the coupling member 40a has the groove portion 49 which extends from substantially the center portion of the base portion 41a toward the shaft receiving portion 42 and which leads to a cavity defined inside the tubular coupling member 40a. The groove portion 49 allows the key-shaped portion 46 to pass through during the sliding of the slide rod 43 so that the key-shaped portion 46 does not obstruct the sliding operation.

The cam portion 32 is provided at one end of the support shaft 31a. The cam portion 32 may be prepared separately from a shaft portion of the support shaft 31a to be secured to the shaft portion, or may be formed integrally with the shaft portion. In the cam portion 32, a predetermined concave-convex shape is formed at the peripheral portion of a part of a substantially disc-shaped cam base member. In the example, a convex portion 32a is formed between a concave portion 32b and a notched portion 32c.

The hinge portion 30 is formed by fitting the support shaft 31a in a ring portion 48 of the shaft receiving portion 42 of the coupling member 40a.

The respective materials forming the coupling member 40a, the slide rod 43a, and the support shaft 31a are not specifically limited, and it is desired that the coupling member 40a, the slide rod 43a, and the support shaft 31a should each be made of a rigid material.

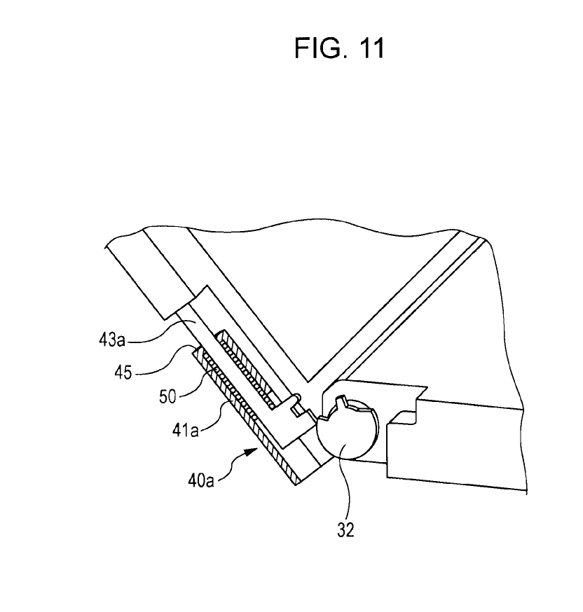

As shown in FIG. 11, the lower end and the upper end of the helical spring 50 housed inside the coupling member 40a contact the key-shaped portion 46 and the inner wall of the end wall surface 45 of the coupling member 40a, respectively. The helical spring 50 applies an urging force for urging the slide rod 43 downward (in the opposite direction to the direction in which the slide rod 43 projects from the guide member, that is, toward the hinge portion 30) at all times. Although the helical spring 50 is not a necessary element of the present disclosure, the presence of the helical spring 50 prevents backlash between the upper housing 10 and the lower housing 20, especially backlash during an opening/closing operation of the upper housing 10.

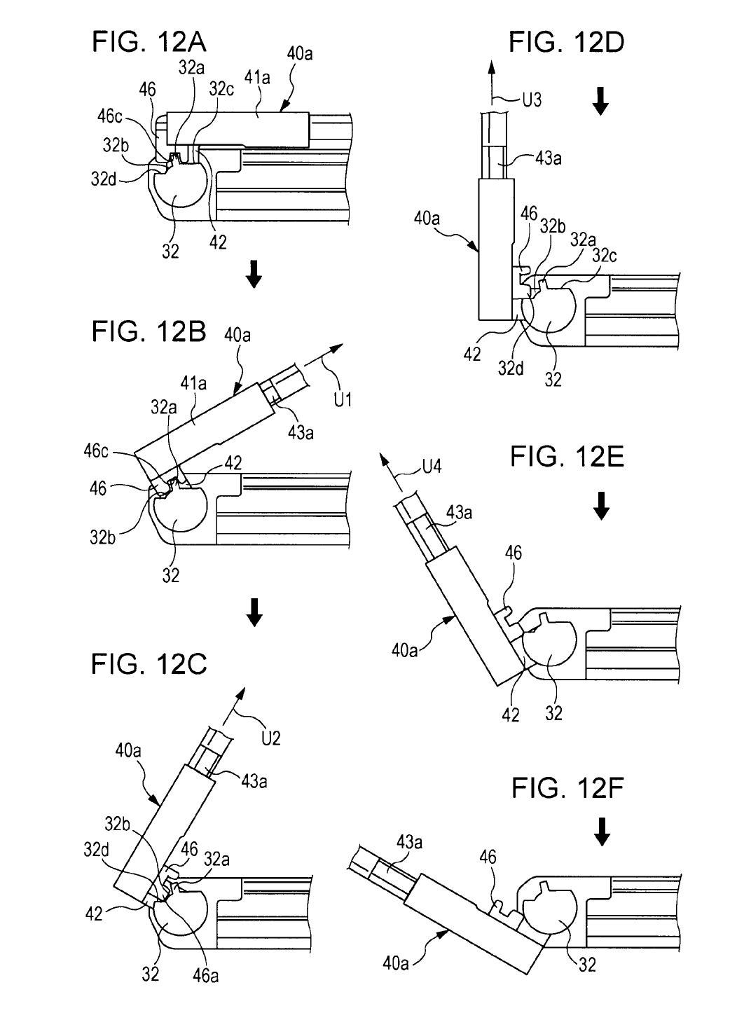

FIG. 12 illustrates a specific operation of the coupling member 40a in the portable terminal shown in FIG. 8. FIGS. 12(a) to 12(d) show the relationship between the cam portion 32 and the coupling member 40a (and the slide rod 43a) at each stage. including intermediate stages, in the course in which the upper housing 10 moves from the closed state (first rotational position) to the open state at a predetermined angle (second rotational position). It should be noted that the cam portion 32 is stationary with respect to the lower housing 20 at any stage. When the upper housing 10 rotates with respect to the lower housing 20, the state of engagement of the key-shaped portion 46 of the slide rod 43 with the cam portion 32 varies to slide the slide rod 43 in the coupling member 40a.

In the closed state of FIG. 12(a), the convex portion 32a of the cam portion 32 is fitted in the concave portion 46c of the key-shaped portion 46 of the slide rod 43. In this state, the helical spring 50 in the coupling member 40a has been elongated into the longest state.

FIG. 12(b) shows a state in which the upper housing 10 is opened by a rotational angle of about 30 degrees. In this state, the coupling member 40a is inclined at the same angle together with the slide rod 43 inside the coupling member 40a. In this state, the convex portion 32a of the cam portion 32 is still fitted in the concave portion 46c of the key-shaped portion 46 of the slide rod 43. However, with the shaft receiving portion 42 rotated about the support shaft 31 of the hinge portion 30, the slide rod 43 has been moved obliquely upward (in the direction of an arrow U1) relative to the coupling member 40a against the spring force of the helical spring 50. Thus, the upper housing 10 has been floated up in the same direction.

FIG. 12(c) shows a state in which the upper housing 10 is opened by about 60 degrees. In this state, the coupling member 40a is inclined at the same angle together with the slide rod 43 inside the coupling member 40a. In this state, the convex portion 32a of the cam portion 32 is disengaged from the concave portion 46c of the key-shaped portion 46 of the slide rod 43, and instead the convex portion 46a of the key-shaped portion 46 is fitted in the concave portion 32b of the cam portion 32. In this state, with the shaft receiving portion 42 further rotated about the support shaft 31 of the hinge portion 30, the slide rod 43 has been moved obliquely upward (in the direction of an arrow U2) relative to the coupling member 40a. Thus, the upper housing 10 has been further floated up in the same direction. At this time, the helical spring 50 has been compressed compared to the state of FIG. 12(b).

FIG. 12(d) shows a state in which the upper housing 10 is opened by 90 degrees. In this state, the coupling member 40a stands upright together with the slide rod 43 inside the coupling member 40a. In this state, the convex portion 46a of the key-shaped portion 46 is disengaged from the concave portion 32b of the cam portion 32, and a side wall 32d of the concave portion 32b of the cam portion 32 is engaged with the lower end portion of the key-shaped portion 46. In this state, with the shaft receiving portion 42 further rotated about the support shaft 31 of the hinge portion 30, the slide rod 43 has been moved upward (in the direction of an arrow U3) relative to the coupling member 40a. Thus, the upper housing 10 has been further floated up in the same direction. At this time, the helical spring 50 has been compressed compared to the state of FIG. 12(c).

FIG. 12(e) shows a state in which the upper housing 10 is opened by about 120 degrees. In this state, the coupling member 40a is inclined at the same angle together with the slide rod 43 inside the coupling member 40a. In this state, the upper end portion of the side wall 32d of the concave portion 32b of the cam portion 32 is still engaged with the lower end portion of the key-shaped portion 46. With the shaft receiving portion 42 rotated about the support shaft 31 of the hinge portion 30 to the rear of the cam portion 32 (on the left side of the drawing), the slide rod 43 has been moved upward (in the direction of an arrow U4) relative to the coupling member 40a. Thus, the upper housing 10 has been further floated up in the same direction. At this time, the floating amount (projecting amount) is maximum. The helical spring 50 has been compressed compared to the state of FIG. 12(d). The length of the helical spring 50 is minimum.

FIG. 12(f) shows a state in which the upper housing 10 is opened by about 150 degrees. In this state, the coupling member 40a is inclined at the same angle together with the slide rod 43 inside the coupling member 40a. Also, the circumferential portion of the concave portion 32b of the cam portion 32 contacts the lower end portion of the key-shaped portion 46. After the convex portion 46a of the key-shaped portion 46 has moved on the circumferential portion of the cam portion 32, the positional relationship between the slide rod 43a and the coupling member 40a no longer varies even if the shaft receiving portion 42 is further rotated about the support shaft 31 of the hinge portion 30 to the rear of the cam portion 32 (on the left side of the drawing). That is, after the upper housing 10 reaches the opening angle of FIG. 12(e), the amount by which the slide rod 43a projects from the coupling member 40a does not vary even if the upper housing 10 is further opened. Accordingly, the floating amount of the upper housing 10 also does not vary but remains the maximum. Also, the length of the helical spring 50 does not vary but remains the minimum. Thus, the range of the opening angle that is larger than the opening angle of FIG. 12(e) is a so-called play region in which variations in opening angle of the upper housing 10 are not reflected in the projecting amount of the upper housing 10. The helical spring 50 serves to maintain the slide rod 43a, and hence the upper housing 10, in a stable state especially in such a play region.

The transition of the upper housing 10 from the open state to the closed state simply follows the steps described above in the reversed order, and thus is not described in detail.

According to the second embodiment, it is possible to automatically float up and retract the upper housing 10 by the user simply opening and closing the upper housing 10 with respect to the lower housing 20.

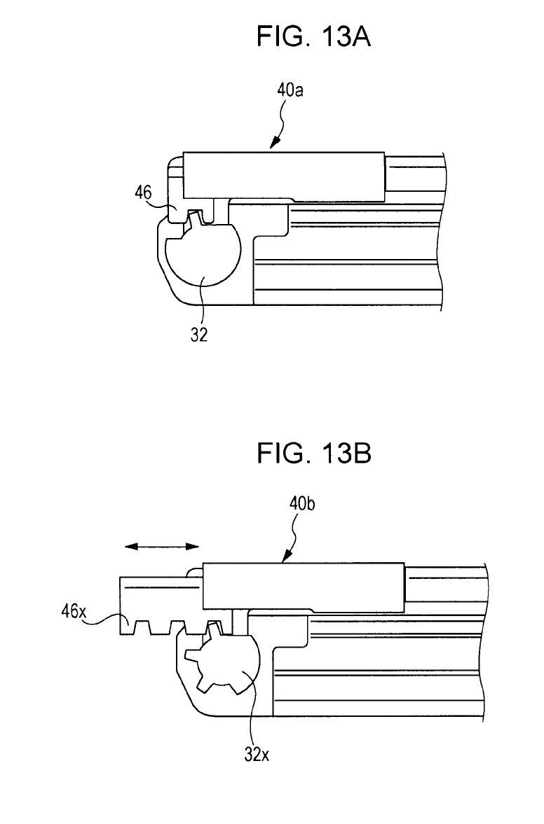

FIG. 13 illustrates a modification of the second embodiment. FIG. 13(a) shows the coupling member 40a according to the second embodiment discussed above, and FIG. 13(b) shows a coupling member 40b according to the modification. In the modification, the key-shaped portion 46 of the slide rod 43a is replaced with a key-shaped portion 46x, and the cam portion 32 of the support shaft 31a is replaced with a cam portion 32x. The key-shaped portion 46x and the cam portion 32x correspond to a so-called rack and pinion. The mechanism of FIG. 13(a) also may be considered as a rack and a pinion on a small scale.

The configuration of the modification is basically the same as that according to the second embodiment described above, and thus overlapping descriptions are omitted. The key-shaped portion 46x has an increased number of concave portions and convex portions compared to those of the key-shaped portion 46. Also, the cam portion 32x has an increased number of concave portions and convex portions compared to those of the cam portion 32.

According to the modification, it is possible to increase the angular range over which variations in opening angle of the upper housing 10 are reflected in the projecting amount of the upper housing 10 compared to that according to the second embodiment. That is, it is possible to reduce or eliminate the play region described above. Also in the modification, the helical spring 50 has the effect of preventing backlash accompanied by an opening/closing operation of the upper housing 10, but is not a necessary element.

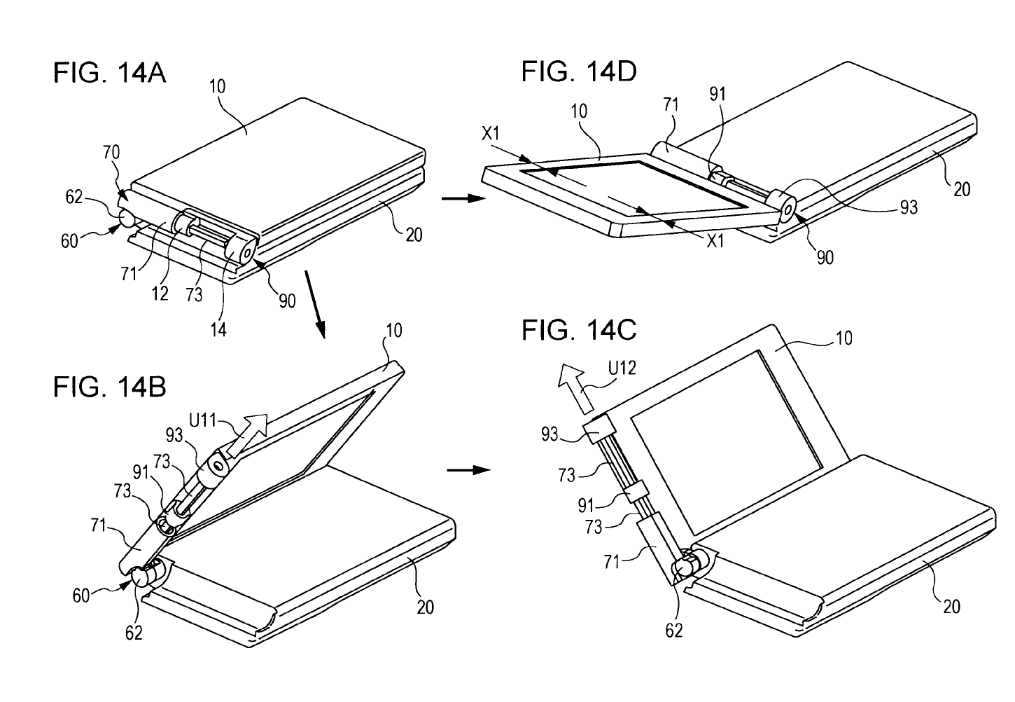

FIG. 14 illustrates a third embodiment of the present disclosure.

In the embodiment, the present disclosure is applied to a so-called two-axis hinge-type portable terminal. In the two-axis hinge-type portable terminal, as shown in FIGS. 14(a) to 14(c), the upper housing 10 and the lower housing 20 are opened and closed (horizontally opened) about a first axis extending along the long side (a second side which is orthogonal to a first side) of the upper housing 10 and the lower housing 20. When horizontally opened, a coupling member 70 operates to project the upper housing 10 upward (U11, S12) with respect to the horizontally opening direction along with an opening operation of the upper housing 10 as in the second embodiment. In general, a display screen has a rectangular shape, and the size of the display screen in the vertical direction is smaller when the portable terminal is horizontally opened. Therefore, it is significant to apply the present disclosure to the horizontally opening portable terminal.

In the portable terminal according to the third embodiment, as shown in FIGS. 14(a) and 14(d), the upper housing 10 and the lower housing 20 are opened and closed (vertically opened) about a second axis extending along the short side (first side) of the upper housing 10 and the lower housing 20. In order to enable vertical opening in addition to horizontal opening, the coupling member 70 is provided only at one end of one side of the terminal in the longitudinal direction.

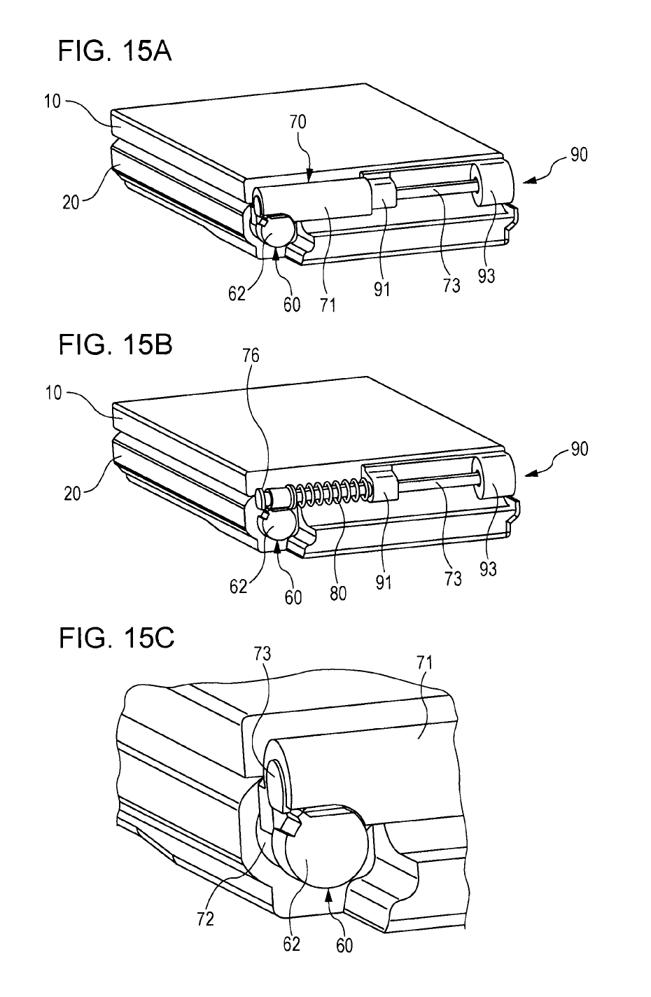

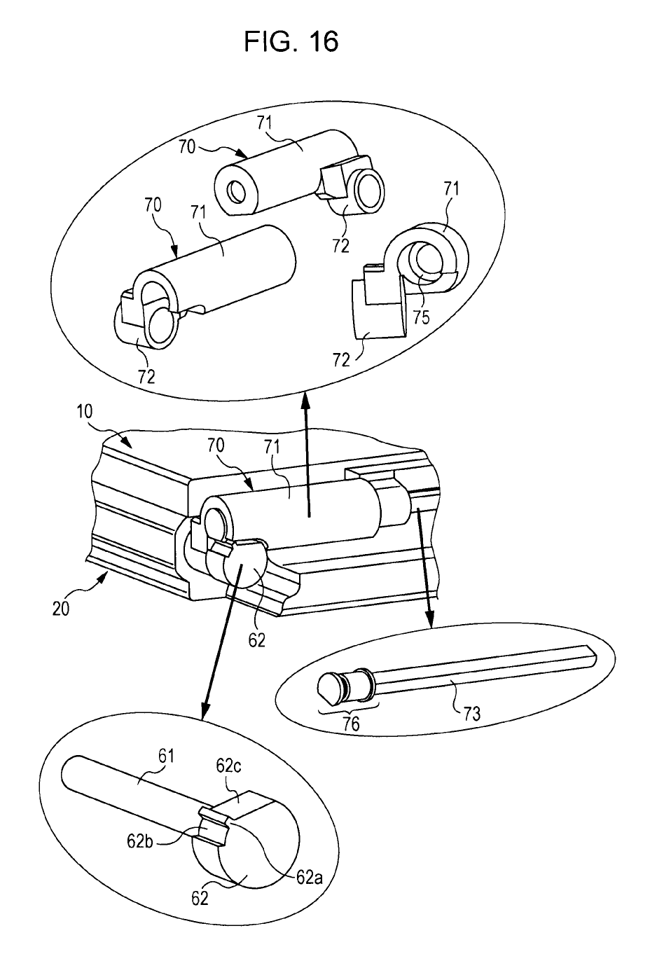

The configuration of a portion of the third embodiment will be described with reference to FIGS. 15 to 17. FIG. 15(a) shows the configuration of a coupling portion between the upper housing 10 and the lower housing 20 in the closed state. FIG. 15(b) shows the coupling portion of FIG. 15(a) with some components removed. FIG. 15(c) shows a hinge portion 60 of FIG. 15(a) as enlarged. FIGS. 16(a) to 16(c) show some constituent elements in an exploded state.

The hinge portion 60 is a horizontally opening hinge portion, and is formed by a shaft receiving portion 72 of the coupling member 70 and a support shaft 61. The hinge portion 60 functions as a first hinge portion that allows an opening/closing operation of the upper housing 10 about a rotary shaft extending along (in parallel with) one long side of the lower housing 20. As shown in FIG. 16, the support shaft 61 passes through a through hole in the shaft receiving portion 72, which projects from one end of a base portion 71 of the coupling member 70, to be fixed inside an end portion of one long side of the lower housing 20. In the support shaft 61, a predetermined concave-convex shape is formed at the peripheral portion of a part of a substantially disc-shaped cam base member as with the cam portion 32 of the support shaft 31 according to the second embodiment. That is, a convex portion 62a is formed between a concave portion 62b and a notched portion 62c at the periphery of the cam base member.

When horizontally opened, the coupling member 70, the cam portion 62 of the support shaft 61, and a helical spring 80 function in the same way as the coupling member 40, the cam portion 32, and the helical spring 50, respectively, according to the second embodiment.

The slide rod 73 has a large-diameter portion at one end, and a cylindrical key-shaped portion 76 is formed at the large-diameter portion. The concave-convex shape of the key-shaped portion 76 is formed over the entire circumference of the slide rod 73 so that the key-shaped portion 76 is well supported inside the base portion 71 even if the slide rod 73 is rotated with respect to the cam portion 62 to any rotational angle when vertically opened. That is, the key-shaped portion 76 of the slide rod 73 is formed in a rotationally symmetrical shape about the center axis of the slide rod 73 in the longitudinal direction.

A cylindrical surface on one side of the large-diameter portion at one end of the slide rod 73 may be cut, and the key-shaped portion 76 may be formed in the cut surface. In this case, the slide rod 73 may be configured to be non-rotatable with respect to the cam portion 62 so that the cut surface of the slide rod 73 is maintained in contact with the cam portion 62. Along with this configuration, the upper housing 10 is configured to be rotatably supported by the slide rod 73. With the key-shaped portion 76 and the cam portion 62 in surface contact with each other, it is possible to mitigate abrasion due to friction between the convex portion of the key-shaped portion 76 and the cam portion 62. In the case of a configuration in which the slide rod 73 does not rotate with respect to the cam portion 62, it is not necessary that the concave-convex shape of the key-shaped portion 76 should be formed over the entire circumference of the slide rod 73.

As best shown in FIG. 15(a), a hinge portion 90 is a vertically opening hinge portion, and is formed by the slide rod 73 and rod receiving portions 91 and 93. The hinge portion 90 functions as a second hinge portion that allows an opening/closing operation of the upper housing 10 about a rotary shaft extending along (in parallel with) one short side of the upper housing 10 which is orthogonal to the one long side described above. The slide rod 73 is coupled to the lower housing 20 via the base portion 71 of the coupling member 70 and the hinge portion 60. The rod receiving portions 91 and 93 may be fixed to or formed integrally with an end portion of the upper housing 10. The slide rod 73 has a non-circular cross section to be non-rotatably engaged with the rod receiving portions 91 and 93 so that the slide rod 73 is rotated along with opening and closing of the upper housing 10 when the upper housing 10 is vertically opened with respect to the lower housing 20. Instead, the slide rod 73 may be configured to be non-rotatable in conjunction with opening and closing of the upper housing 10. In any case, a mechanism that maintains the open/closed state of the upper housing 10 when vertically opened through the hinge portion 90 may be provided at an exposed portion of the slide rod 73 in FIG. 15(a). The specific configuration of the mechanism is not directly related to the present disclosure, and thus is not described.

The base portion 71 of the coupling member 70 functions to keep the distance and the relationship between the respective axes of the hinge portion 60 and the hinge portion 90 constant. In the embodiment, the respective axes of the hinge portion 60 and the hinge portion 90 are in a so-called skew relationship with respect to each other. This enables a compact two-axis hinge structure.

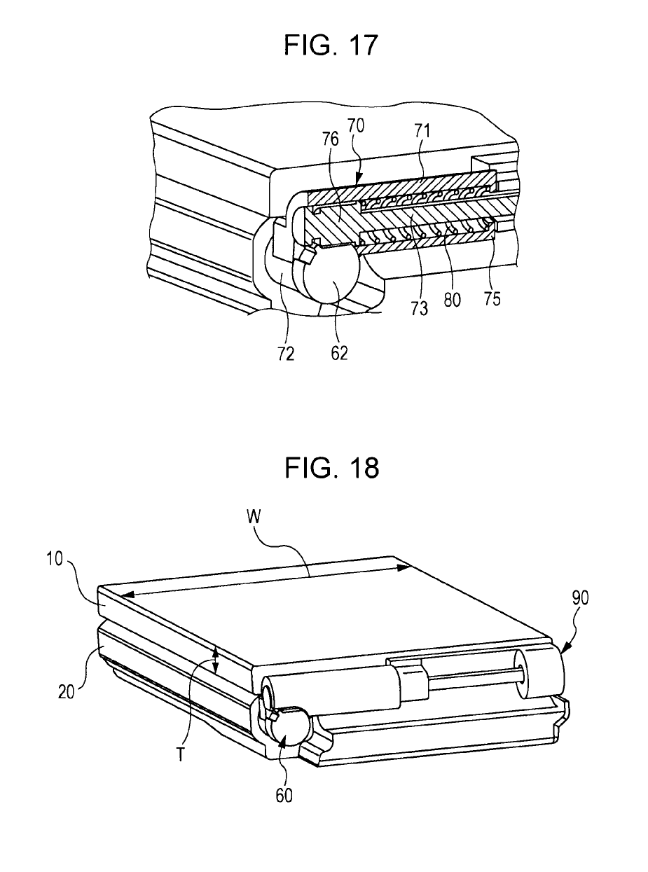

FIG. 17 shows a cross sectional shape of the coupling member 70. The helical spring 80 is housed in an internal cavity of the base portion 71 with a small-diameter portion of the slide rod 73 passing through a space inside the helical spring 80. One end of the helical spring 80 contacts the inner wall of an end wall surface 75 of the base portion 71, and the other end of the helical spring 80 contacts a side surface of a large-diameter portion provided with the key-shaped portion 76.

Without using the present disclosure, in a one-axis horizontally opening portable terminal, the display screen itself may be displaced toward one side (upward in the open state) to improve the viewability. In this case, in a two-axis hinge-type portable terminal, however, the display screen may be laterally asymmetrical when vertically opened to give a sense of discomfort. According to the embodiment, in contrast, even if the display screen in the vertically opening state is disposed laterally symmetrically (with equal left and right margins X1) with respect to substantially the entire area of the upper housing as shown in FIG. 14(d), the display screen in the horizontally opening state shown in FIG. 14(c) is not degraded in viewability. Thus, the embodiment may be said to be highly compatible with a two-axis hinge-type portable terminal.

According to the third embodiment, as shown in FIG. 18, it is possible to dispose the display screen with equal margins on both sides with respect to substantially the entire width W (the size of the short side) of the upper housing 10 even in a two-axis configuration with the horizontally opening hinge portion 60 and the vertically opening hinge portion 90. In addition, it is possible to sufficiently reduce the thickness T of the upper housing regardless of the hinge diameter of the hinge portion 60. Moreover, the hinge portion 60 or the hinge portion 90 does not project from a side portion of the housing.

According to the embodiments of the present disclosure, as discussed above, it is possible to reduce the size and the thickness of a clamshell-type portable terminal and a portable terminal with two vertical and horizontal axes by arranging components efficiently and without degrading the usability, by using a hinge structure allowing sliding in the direction away from a rotary shaft along with an opening operation. In addition, it is possible to obtain a good viewability of the display screen in the open state without reducing the display area of the display device disposed in the upper housing and without providing a notch in a part of the upper housing.

While preferred embodiments of the present disclosure have been described above, various changes and modifications other than those mentioned above may be made. That is, it should be understood as a matter of course by those skilled in the art that various modifications, combinations, and other embodiments may occur depending on design requirements and other factors insofar as they are within the scope of the appended claims or the equivalents thereof.

1. A terminal apparatus comprising:
a first housing;
a second housing; and
a hinge mechanism that slidably couples the first housing to the second housing in each of an open state and a closed state with respect to the second housing, wherein
the hinge mechanism includes a base portion and a movable portion, the movable portion being slidable with respect to the base portion in a direction which the first housing moves away from the second housing when the first housing transitions from the closed state to the open state with respect to the second housing.

2. The terminal apparatus of claim 1, wherein the base portion includes a retention portion that maintains the movable portion at a predetermined position after being moved in the direction away from the second housing.

3. The terminal apparatus of claim 1, wherein the movable portion is slidable a direction which the first housing moves toward the second housing when the first housing transitions from the open state to the closed state with respect to the second housing.

4. The terminal apparatus of claim 3, wherein the base portion includes a retention portion that maintains the movable portion at a predetermined position after being moved in the direction toward the second housing.

5. The terminal apparatus of claim 1, wherein the movable portion is a rod-shaped member attached to the first housing.

6. The terminal apparatus of claim 5, wherein the base portion is a cylinder-shaped member that has an internal space in which the rod-shaped member slides.

7. The terminal apparatus of claim 6, wherein the rod-shaped member includes a portion having a first diameter and a portion having a second diameter, which is larger than the first diameter.

8. The terminal apparatus of claim 7, wherein an outer periphery of the portion having the second diameter contacts an inner wall of the cylinder-shaped member.

9. The terminal apparatus of claim 8, wherein the cylinder-shaped member includes a projection that stops the portion having the second diameter of the rod-shaped member at a predetermined position after being moved in the direction away from the second housing.

10. The terminal apparatus of claim 8, wherein the cylinder-shaped member includes a projection that stops the portion having the second diameter of the rod-shaped member at a predetermined position after being moved in the direction toward the second housing.

11. The terminal apparatus of claim 1, wherein the base portion is rotatably connected to the second housing.

12. The terminal apparatus of claim 11, wherein the base portion includes a shaft-receiving portion projecting in a lateral direction from one end of the base portion.

13. The terminal apparatus of claim 12, wherein the shaft-receiving portion is coupled to a shaft disposed at a rear end portion of the second housing that extends in parallel with a rear side of the second housing.

14. The terminal apparatus of claim 1, wherein one end of the movable portion is connected to the first housing and another end of the movable portion includes a concave-convex portion.

15. The terminal apparatus of claim 14, further comprising:
a cam portion that is fixed to the second housing and engages with the convex-concave portion of the movable portion.

16. The terminal apparatus of claim 15, wherein the movable portion slides with the convex-concave portion engageably rotating with respect to the cam portion such that the movable portion slides with respect to the base portion in a direction which the first housing moves away from the second housing when the first housing transitions from the closed state to the open state with respect to the second housing.

17. The terminal apparatus of claim 16, wherein the base portion is a cylinder-shaped member that has an internal space in which the movable portion slides.

18. The terminal apparatus of claim 17, further comprising:
an elastic member that applies a force in an opposite direction to a direction in which the member projects from the cylinder-shaped member.

19. The terminal apparatus of claim 18, wherein the elastic member is located within the cylinder-shaped member, and surrounds a portion of the movable portion located within the cylinder-shaped member.

20. The terminal apparatus of claim 19, wherein the elastic member is in contact with an upper end of the cylinder-shaped member and is in contact with the concave-convex portion of the movable portion.
